(19) United States
(12) Patent Application Publication
(10) Pub. No.: US 2026/0304625 A1
(43) Pub. Date: Oct. 1, 2026

(54) PHASE SHIFTER ASSEMBLY

(71) Applicant: Suzhou Luxshare Technology Co., Ltd., Suzhou City (CN)

(72) Inventors: GANG ZHOU, Suzhou City (CN); ZHENGGUO ZHOU, Suzhou City (CN); WENKAI XU, Suzhou City (CN)

(73) Assignee: Suzhou Luxshare Technology Co., Ltd., Suzhou City (CN)

(21) Appl. No.: 19/373,956

(22) Filed: Oct. 30, 2025

(30) Foreign Application Priority Data
Mar. 25, 2025 (CN) 202520536010.0

(51) Int. Cl. H05K 1/14

(52) U.S. Cl. CPC H05K 1/141; H05K 2201/09036; H05K 2201/10393

(57) ABSTRACT

A phase shifter assembly includes a first circuit board, a second circuit board, a first limiting structure and a second limiting structure. The first circuit board is provided with a first strip. The second circuit board is sandwiched between the first circuit board and the first limiting structure, and is provided with a second strip. The first limiting structure is fixed to the first circuit board and presses the second circuit board toward the first circuit board to clamp the second circuit board between the first limiting structure and the first circuit board. The second limiting structure is fixed to the second circuit board and pushes the second circuit board to move relative to the first circuit board in such a manner that the second strip contacts and is electrically connected to different positions on the first strip for phase shifting.

### CROSS-REFERENCE TO RELATED APPLICATION

This application claims the benefit of Chinese Patent Application No. 202520536010.0, filed on Mar. 25, 2025, entitled “Phase Shifter Assembly”, which is incorporated herein by reference in its entirety.

### TECHNICAL FIELD

The present disclosure relates to the field of 5G communication, and in particular to a phase shifter assembly.

### BACKGROUND

With the development of 5G communication technology, higher performance requirements have been put forward for signal processing devices. As a key component in signal processing, a phase shifter’s performance directly affects signal quality and system stability. An existing phase shifter assembly has problems such as a complex structure, low assembly efficiency, a high material cost, etc. Meanwhile, it is difficult to achieve high-precision phase control, leading to poor consistency in antenna performance and failing to meet the requirements of a 5G communication system.

### SUMMARY

The present disclosure provides a phase shifter assembly.

A phase shifter assembly includes: a first circuit board, a second circuit board, a first limiting structure, and a second limiting structure.

The first circuit board is provided with a first strip. The second circuit board is placed on the first circuit board and provided with a second strip on one side facing the first circuit board. The second strip contacts and is electrically connected to the first strip. The first limiting structure is fixed to the first circuit board and presses the second circuit board toward the first circuit board, and the second circuit board is movably clamped between the first limiting structure and the first circuit board. The second limiting structure is fixed to the second circuit board and configured to push the second circuit board to move relative to the first circuit board in such a manner that the second strip contacts and is electrically connected to different positions of the first strip for phase shifting.

In some embodiments, the first limiting structure includes a first body piece located on the second circuit board and provided with a first snap, and the first snap snap-fits on one side, away from the second circuit board, of the first circuit board.

In some embodiments, the first body piece is further provided with an elastic pressing sheet, and the elastic pressing sheet presses the second circuit board toward the first circuit board.

In some embodiments, the first limiting structure further includes: a rivet and an elastic clamping sheet. The rivet fixes the first body piece and the first circuit board. The elastic clamping sheet is located on one side, away from the second circuit board, of the first circuit board and fastens the rivet.

In some embodiments, a guide groove is formed in the second circuit board, the first body piece extends toward the first circuit board to form a guide block which is movably arranged within the guide groove, and the rivet penetrates through the guide block.

In some embodiments, the rivet includes: a rod body and a top cap. The rod body is provided with an annular groove at a first end, and the annular groove is matched with the elastic clamping sheet. The top cap is located at a second end of the rod body and has a sectional size larger than that the rod body.

In some embodiments, the elastic clamping sheet is arranged in a dome-shaped structure with a through hole formed in a center, and the elastic clamping sheet is provided with a plurality of slits arranged around the through hole as the center. An end surface of the first end of the rod body is arranged as a spherical surface with a partial region protruding to form an inserting portion, and the inserting portion is matched with the slits.

In some embodiments, the first body piece is provided with an accommodating groove matched with the top cap.

In some embodiments, the first circuit board is provided with an avoidance groove allowing the first snap to pass through.

In some embodiments, the second limiting structure includes a second body piece located on the second circuit board. The second body piece is provided with a second snap, and the second snap snap-fits on one side, facing the first circuit board, of the second circuit board.

In some embodiments, the first circuit board is provided with a limiting groove for accommodating the second snap.

In some embodiments, the second body piece extends toward the first circuit board to form an assembly column, and the second circuit board is provided with an assembly hole matched with the assembly column.

In some embodiments, the phase shifter assembly further includes a drive mechanism connected to the second limiting structure, and the drive mechanism pushes the second circuit board to move relative to the first circuit board by means of the second limiting structure.

In some embodiments, the drive mechanism includes a motor, a transmission piece and a connecting piece. The motor is connected to the transmission piece, and the transmission piece is connected to the connecting piece. The second limiting structure is provided with a connecting column connected to the connecting piece.

### BRIEF DESCRIPTION OF DRAWINGS

The foregoing and other objectives, features and advantages of the present disclosure will become more apparent from the following description of embodiments of the present disclosure with reference to the accompanying drawings, in which:

FIG. 1 is a schematic diagram of a phase shifter assembly provided by an embodiment of the present disclosure;

FIG. 2 is a schematic diagram of a partial structure of a phase shifter assembly provided by an embodiment of the present disclosure;

FIG. 3 is a schematic exploded diagram of a partial structure of a phase shifter assembly provided by an embodiment of the present disclosure;

FIG. 4 is a schematic diagram of a first circuit board provided by an embodiment of the present disclosure;

FIG. 5 is a schematic diagram of a second circuit board provided by an embodiment of the present disclosure;

FIG. 6 is a schematic diagram of a first body piece provided by an embodiment of the present disclosure;

FIG. 7 is a schematic diagram of the first body piece provided by an embodiment of the present disclosure from another perspective;

FIG. 8 is a schematic diagram of a rivet provided by an embodiment of the present disclosure;

FIG. 9 is a schematic diagram of an elastic pressing sheet provided by an embodiment of the present disclosure;

FIG. 10 is a schematic diagram of a second body piece provided by an embodiment of the present disclosure; and

FIG. 11 is a schematic diagram of the second body piece provided by an embodiment of the present disclosure from another perspective.

### REFERENCE NUMERALS OF THE DRAWINGS

1-first circuit board; 11-first strip; 12-avoidance groove; 13-limiting groove; 14-second positioning hole; 2-second circuit board; 21-second strip; 22-guide groove; 23-assembly hole; 3-first limiting structure; 31-first body piece; 311-first snap; 312-elastic pressing sheet; 313-guide block; 314-accommodating groove; 315-hole; 316-first positioning hole; 32-rivet; 321-rod body; 3211-annular groove; 3212-inserting portion; 322-top cap; 33-elastic clamping sheet; 331-through hole; 332-slit; 4-second limiting structure; 41-second body piece; 411-second snap; 412-assembly column; 413-connecting column; 5-drive mechanism; 51-motor; 52-transmission piece; 53-connecting piece.

### DETAILED DESCRIPTION OF THE EMBODIMENTS

The present application is described below based on embodiments, but the present application is not only limited to these embodiments. In the following detailed description of the present application, some specific details are described in detail. The present application can also be fully understood by those skilled in the art without the description of these details. In order to avoid confusing the substance of the present application, well-known methods, processes, flows, elements and circuits are not described in detail.

Moreover, those of ordinary skill in the art should understand that the accompanying drawings provided herein are for the purpose of illustration only, and the accompanying drawings are not necessarily drawn to scale.

Unless otherwise specified and limited, the terms "mounted", "connected", "connection", "fixed", and the like should be understood in a broad sense. For example, the "connection" may be fixed connection, detachable connection, integration, mechanical connection, electrical connection, direct connection, indirect connection by a medium, internal communication of two elements, or interaction between two elements. Those of ordinary skill in the art can understand the specific meanings of the above terms in the present application according to specific circumstances.

For ease of explanation, the spatial terms such as "inside", "outside", "below", "under", "lower part", "above", and "upper part" are used here to describe the relationship between one element or feature and the other element or feature illustrated in the drawings. Understandably, the spatial terms are intended to include different orientations of a device during use or operation, besides those depicted in the figures. For example, if the device in the drawings is flipped, the element described as being "under" or "below" the other element or feature will be positioned "above" the other element or feature. Therefore, the example term "below" can encompass both the directions above and below. The device can be oriented in other ways (rotated 90 degrees or in other orientations), and the spatial descriptors used here should be explained accordingly.

Unless explicitly required by the context, the terms such as "include" and "contain" in the entire application document should be interpreted as including rather than exclusive or exhaustive, that is, "include but not limited to".

In the description of the present application, it should be understood that the terms "first", "second", etc. are only used for descriptive purposes and cannot be understood as indicating or implying relative importance. Moreover, in the description of the present application, unless otherwise stated, "a plurality of" means two or more.

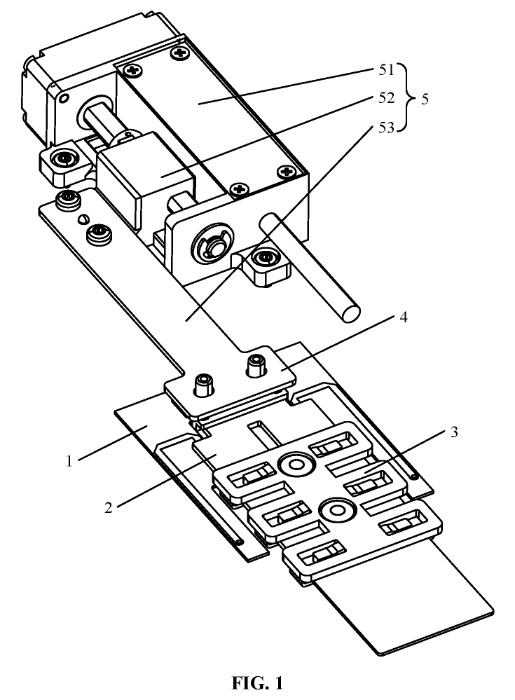

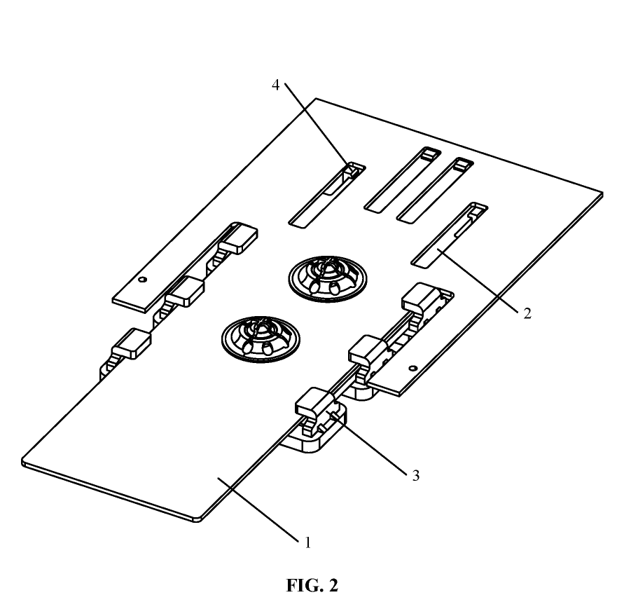

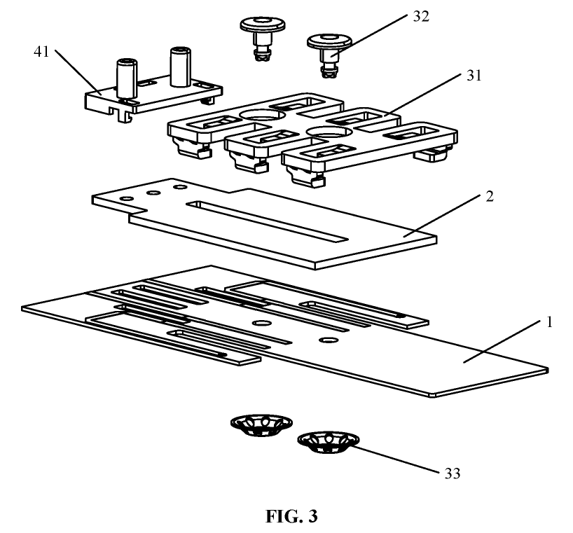

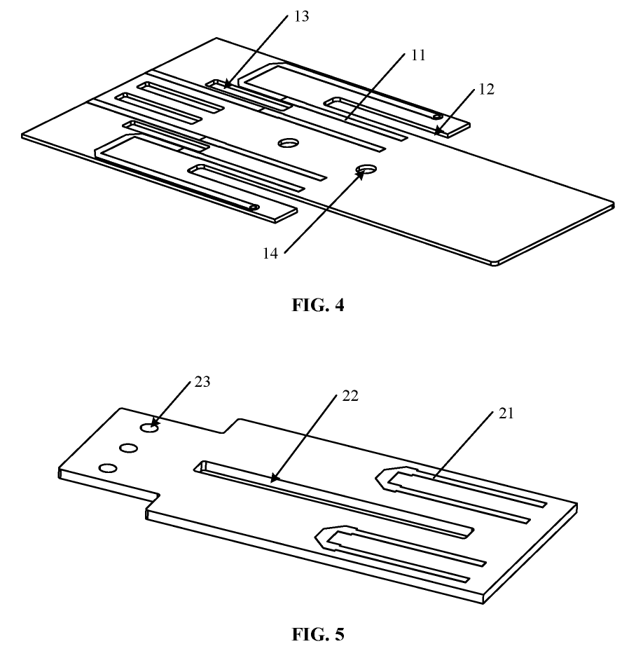

FIG. 1 is a schematic diagram of a phase shifter assembly provided by an embodiment of the present disclosure, FIG. 2 is a schematic diagram of a partial structure of a phase shifter assembly provided by an embodiment of the present disclosure, and FIG. 3 is a schematic exploded diagram of a partial structure of a phase shifter assembly provided by an embodiment of the present disclosure. As shown in FIGS. 1-3, the phase shifter assembly includes a first circuit board 1, a second circuit board 2, a first limiting structure 3 and a second limiting structure 4. It is noted that FIG. 4 is a schematic diagram of a first circuit board provided by an embodiment of the present disclosure. As shown in FIG. 4, the first circuit board 1 is provided with a first strip 11. Correspondingly, FIG. 5 is a schematic diagram of a second circuit board provided by an embodiment of the present disclosure. As shown in FIG. 5, the second circuit board 2 is provided with a second strip 21. It is noted that the first circuit board 1 and the second circuit board 2 are each a single-sided network. The second circuit board 2 is placed on the first circuit board 1, and the second strip 21 is arranged on one side facing the first circuit board 1. The second strip 21 contacts and is electrically connected to the first strip 11. Further, the first limiting structure 3 is fixed to the first circuit board 1 and presses the second circuit board 2 toward the first circuit board 1, so that the second circuit board 2 is movably clamped between the first limiting structure 3 and the first circuit board 1 while ensuring stable contact and electrical connection between the first strip 11 and the second strip 21. More further, the second limiting structure 4 is fixed to the second circuit board 2 and configured to push the second circuit board 2 to move relative to the first circuit board 1, so that the second strip 21 contacts and is electrically connected to different positions of the first strip 11 for phase shifting. Thus, the phase shifter assembly’s structure is simplified by cooperation of the first limiting structure 3 and the second limiting structure 4, thereby enhancing assembly efficiency and reducing a material cost while enabling high-precision phase control to improve consistency in antenna performance.

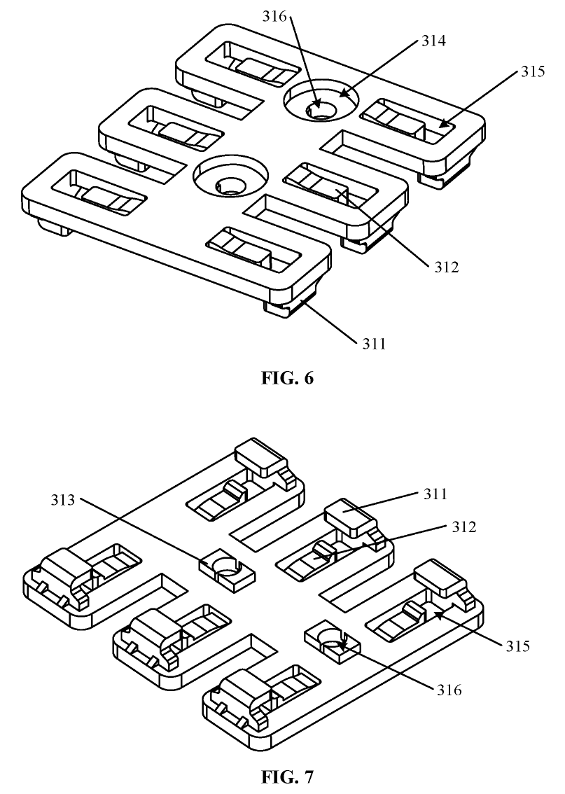

As shown in FIGS. 1-3, in some embodiments, the first limiting structure 3 includes a first body piece 31 which is located on the second circuit board 2. FIG. 6 is a schematic diagram of a first body piece provided by an embodiment of the present disclosure, and FIG. 7 is a schematic diagram of the first body piece provided by an embodiment of the present disclosure from another perspective. As shown in FIGS. 6 and 7, the first body piece 31 is provided with a first snap 311. It is noted that the first snap 311 is arranged in a hook-shaped structure, and its quantity and position is set as needed. Exemplarily, there are six first snaps 311 symmetrically distributed at two sides edges of the first body piece 31. Further, the first snap 311 is snapped on one side, away from the second circuit board 2, of the first circuit board 1, thereby clamping the second circuit board 2 between the first circuit board 1 and the first body piece 31. Thus, when the second circuit board 2 moves relative to the first circuit board 1, the first body piece 31 prevents the second circuit board 2 from being out of contact with the first circuit board 1, thereby avoiding poor circuit connection and ensuring reliable electrical connection.

As shown in FIGS. 6 and 7, in some embodiments, the first body piece 31 is further provided with an elastic pressing sheet 312. It is noted that the elastic pressing sheet 312 presses the second circuit board 2 toward the first circuit board 1, thereby further enabling the second circuit board 2 be in contact with the first circuit board 1 and improving reliable electrical connection. When the first body piece 31 clamps the second circuit board 2 and the first circuit board 1 by means of the first snap 311, the elastic pressing sheet 312 applies a greater pressure to the second circuit board 2 by its own elasticity, thereby ensuring a closer contact between the second circuit board 2 and the first circuit board 1.

As shown in FIGS. 6 and 7, in some embodiments, a hole 315 is formed in the first body piece 31, and the elastic pressing sheet 312 is arranged in the hole 315 so as to press the second circuit board 2. A quantity of the holes 315 is the same as that of the elastic pressing sheets 312. In addition, the holes 315 are distributed on an inner side of the first snap 311, which enables the elastic pressing sheets 312 to be located on the inner side of the first snap 311, thereby allowing the elastic pressing sheets 312 to precisely press against the second circuit board 20.

As shown in FIGS. 1-3, in some embodiments, the first limiting structure 3 further includes a rivet 32 and an elastic clamping sheet 33. For example, the rivet 32 is used for fixing the first body piece 31 and the first circuit board 1, thereby clamping the second circuit board 2 between the first body piece 31 and the first circuit board 1. Further, the elastic clamping sheet 33 is located on one side, away from the second circuit board 2, of the first circuit board 1, and is matched with the rivet 32 by fastening the rivet 32 to fix the first body piece 31 and the first circuit board 1, thereby enabling the second circuit board 2 and the first circuit board 1 to be in contact with each other. Exemplarily, the rivet 32 sequentially passes through the first body piece 31, the second circuit board 2 and the first circuit board 1, and is then its end part is fixed by the elastic clamping sheet 33. The elastic clamping sheet 33, while being abutted against the first circuit board 1, applies an acting force to the rivet 32 by virtue of its own elasticity, thereby enhancing a fastening effect of the rivet 32 on the first body piece 31 and the first circuit board 1. Consequently, the first body piece 31 and the first circuit board 1 can further clamp the second circuit board 2, that is, enables a tighter contact between the second circuit board 2 and the first circuit board 1.

As shown in FIG. 5, in some embodiment, a guide groove 22 is formed in the second circuit board 2. Further, as shown in FIG. 7, the first body piece 31 extends toward the first circuit board 1 to form a guide block 313. Further, the rivet 32 penetrates through the guide block 313. The guide block 313 is movably arranged within the guide groove 22. When the second circuit board 2 moves relative to the first circuit board 1, the guide block 313 moves relative to the guide groove 22. The guide block 313 and the guide groove 22 define a linear movement direction of the second circuit board 2, thereby ensuring reliable electrical connection between the first circuit board 1 and the second circuit board 2.

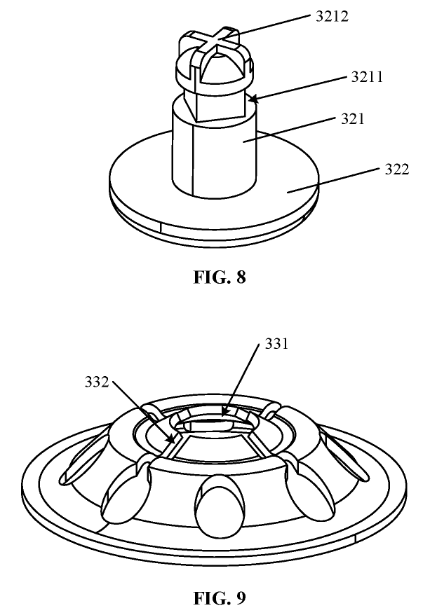

FIG. 8 is a schematic diagram of a rivet provided by an embodiment of the present disclosure. As shown in FIG. 8, in some embodiments, the rivet 32 includes a rod body 321 and a top cap 322. For example, the rod body 321 is arranged in a cylindrical structure and provided with an annular groove 3211 at a first end, and the annular groove 3211 is matched with the elastic clamping sheet 33. In another aspect, the top cap 322 is located at a second end of the rod body 321 and has a sectional size larger than that the rod body 321. For example, the rod body 321 and the top cap 322 both have a circular cross section, the top cap 322 has a sectional diameter larger than that of the rod body 321. The top cap 322 is abutted against the first body piece 31, while the rod body 321 is clamped by the elastic clamping sheet 33. The elastic clamping sheet 33 applies a force to the rod body 321, thereby achieving a fastening effect.

FIG. 9 is a schematic diagram of an elastic pressing sheet provided by an embodiment of the present disclosure. As shown in FIG. 9, in some embodiments, the elastic clamping sheet 33 is arranged in a dome-shaped structure with a through hole 331 formed at a center. Further, a plurality of slits 332 are formed in the elastic clamping sheet 33 and arranged around the through hole 331 as the center. In some embodiments, as shown in FIG. 8, an end surface of the first end of the rod body 321 is arranged as a spherical surface with a partial region protruding to form an inserting portion 3212. The inserting portion 3212 is matched with and inserted into the slit 332. The rod body 321 passes through the through hole 331, and the elastic clamping sheet 33 is clamped within the annular groove 3211. The elastic clamping sheet 33 arches in a direction away from the top cap 322, thereby applying a force to the rivet 32. In this embodiment, there are four slits 332 arranged in a cross shape, and correspondingly, the inserting portion 3212 is formed in a cross structure. In another embodiments, there are two, three, five, or more slits 332, and a shape of the inserting portion 3212 is set corresponding to the quantity and arrangement of the slits 332.

As shown in FIG. 6, in some embodiments, an accommodating groove 314 for accommodating the top cap 322 is formed in the first body piece 31. The accommodating groove 314 is dimensionally matched with the top cap 322. The accommodating groove 314 limits the stretching of the top cap 322, saving the space occupied by the top cap 322. The accommodating groove 314 also provides positioning effect for the installation of the rivet 32.

As shown in FIGS. 6 and 7, in some embodiments, a first positioning hole 316 that penetrates through the guide block 313 is formed at a bottom of the accommodating groove 314. Correspondingly, as shown in FIG. 4, a second positioning hole 14 is formed in the first circuit board 1. Thus, when installing the rivet 32, the top cap 322 of the rivet 32 is arranged in the accommodating groove 314, and the rod body 321 of the rivet 32 sequentially passes through the first positioning hole 316, the guide groove 22, the second positioning hole 14 and the through hole 331. In this way, the rivet 32 and the elastic clamping sheet 33 achieve a fastening effect without affecting movement of the second circuit board 2.

As shown in FIG. 4, in some embodiments, an avoidance groove 12 is formed in the first circuit board 1. For example, the first snap 311 passes through the avoidance groove 12 and then is abutted against one side, away from the second circuit board 2, of the first circuit board 1. A position of the avoidance groove 12 is matched with a size of the second circuit board 2, so that the first snap 311, while snap-fitting the first circuit board 1, is abutted against an edge of the second circuit board 2. This prevents the second circuit board 2 from deviating from a predetermined path in moving.

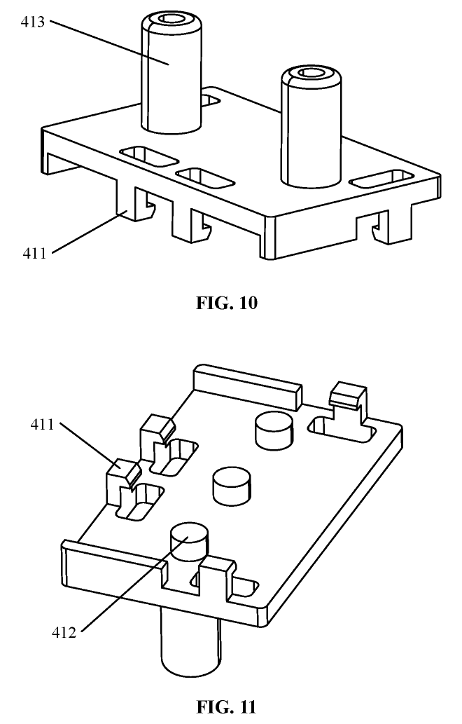

As shown in FIGS. 1-3, in some embodiments, the second limiting structure 4 includes a second body piece 41 located on the second circuit board 2. FIG. 10 is a schematic diagram of a second body piece provided by an embodiment of the present disclosure, and FIG. 11 is a schematic diagram of the second body piece provided by an embodiment of the present disclosure from another perspective. As shown in FIGS. 10 and 11, the second body piece 41 is provided with a second snap 411. For example, the second snap 411 snap-fits on one side, facing the first circuit board 1, of the second circuit board 2. It is noted that a quantity and position of the second snaps 411 can be set as needed. Thus, the second body piece 41 can limit the second circuit board 2 by the second snaps 411, which is conductive to driving the second circuit board 2 to move.

As shown in FIG. 4, in some embodiments, a limiting groove 13 is formed in the first circuit board 1, and the limiting groove 13 accommodates the second snap 411. The limiting groove 13 is shaped and sized to adapt to a movement path of the second snap 411. The limiting groove 13 also guides movement of the second circuit board 2.

As shown in FIG. 11, in some embodiments, the second body piece 41 extends toward the first circuit board 1 to form an assembly column 412. Further, as shown in FIG. 5, an assembly hole 23 is formed in the second circuit board 2. The assembly hole 23 is matched with the assembly column 412. Thus, the second body piece 41 is fixed to the second circuit board 2 for assembly by the assembly column 412, and also applies the acting force to the second circuit board 2 by means of the assembly column 412 to drive the second circuit board 2 to move.

As shown in FIG. 1, in some embodiments, the phase shifter assembly further includes a drive mechanism 5. For example, the drive mechanism 5 is connected to the second limiting structure 4, so as to push the second circuit board 2 to move relative to the first circuit board 1 by means of the second limiting structure 4. In some embodiments, the drive mechanism 5 includes a motor 51, a transmission piece 52 and a connecting piece 53. Further, as shown in FIG. 10, the second body piece 41 of the second limiting structure 4 is provided with a connecting column 413. The connecting piece 53 is connected to the connecting column 413, and the transmission piece 52 is connected to the motor 51 and the connecting piece 53. Thus, the drive mechanism 5 drives the second circuit board 2 to move. In the present embodiment, the transmission piece 52 is a ball screw, which ensures movement accuracy, thereby enabling high-precision phase control and improving consistency in antenna performance.

The embodiments of the present disclosure provide a phase shifter assembly, including a first circuit board, a second circuit board, a first limiting structure and a second limiting structure. The first circuit board is provided with a first strip. The second circuit board is placed on the first circuit board and is provided with a second strip on one side facing the first circuit board. The second strip contacts and is electrically connected to the first strip. The first limiting structure is fixed to the first circuit board and presses the second circuit board toward the first circuit board. The second circuit board is sandwiched between the first limiting structure and the first circuit board. The second limiting structure is fixed to the second circuit board and pushes the second circuit board to move relative to the first circuit board, such that the second strip contacts and is electrically connected to different positions of the first strip for phase shifting. Thus, the phase shifter assembly achieves a simplified structure, thereby enhancing assembly efficiency and reducing a material cost while enabling high-precision phase control to improve consistency in antenna performance.

The above description shows merely exemplary embodiments of the present application, and is not intended to limit the present application. For those skilled in the art, various modifications and changes may be made to the present application. Any modification, equivalent substitution, improvement, and the like made within the spirit and principle of the present application shall fall within the protection scope of the present application.

What is claimed is:

1. A phase shifter assembly, comprising
a first circuit board, provided with a first strip;
a second circuit board, placed on the first circuit board and provided with a second strip on one side facing the first circuit board, the second strip contacting and being electrically connected to the first strip;
a first limiting structure, fixed to the first circuit board and pressing the second circuit board toward the first circuit board, the second circuit board being movably clamped between the first limiting structure and the first circuit board; and
a second limiting structure, fixed to the second circuit board and configured to push the second circuit board to move relative to the first circuit board in such a manner that the second strip contacts and is electrically connected to different positions of the first strip for phase shifting.

2. The phase shifter assembly according to claim 1, wherein the first limiting structure comprises:
a first body piece, located on the second circuit board and provided with a first snap, the first snap snap-fitting on one side, away from the second circuit board, of the first circuit board.

3. The phase shifter assembly according to claim 2, wherein the first body piece is further provided with an elastic pressing sheet, and the elastic pressing sheet presses the second circuit board toward the first circuit board.

4. The phase shifter assembly according to claim 2, wherein the first limiting structure further comprises:
a rivet, fixing the first body piece and the first circuit board; and
an elastic clamping sheet, located on one side, away from the second circuit board, of the first circuit board and fastening the rivet.

5. The phase shifter assembly according to claim 4, wherein a guide groove is formed in the second circuit board; and
the first body piece extends toward the first circuit board to form a guide block which is movably arranged within the guide groove, and the rivet penetrates through the guide block.

6. The phase shifter assembly according to claim 4, wherein the rivet comprises:
a rod body, provided with an annular groove at a first end, the annular groove being matched with the elastic clamping sheet; and
a top cap, located at a second end of the rod body and having a sectional size larger than that the rod body.

7. The phase shifter assembly according to claim 6, wherein the elastic clamping sheet is arranged in a dome-shaped structure with a through hole formed in a center, and the elastic clamping sheet is provided with a plurality of slits arranged around the through hole as the center; and
an end surface of the first end of the rod body is arranged as a spherical surface with a partial region protruding to form an inserting portion, and the inserting portion is matched with the slits.

8. The phase shifter assembly according to claim 6, wherein the first body piece is provided with an accommodating groove matched with the top cap.

9. The phase shifter assembly according to claim 2, wherein the first circuit board is provided with an avoidance groove allowing the first snap to pass through.

10. The phase shifter assembly according to claim 1, wherein the second limiting structure comprises:
a second body piece, located on the second circuit board and provided with a second snap, the second snap snap-fitting on one side, facing the first circuit board, of the second circuit board.

11. The phase shifter assembly according to claim 10, wherein the first circuit board is provided with a limiting groove for accommodating the second snap.

12. The phase shifter assembly according to claim 10, wherein the second body piece extends toward the first circuit board to form an assembly column; and
the second circuit board is provided with an assembly hole matched with the assembly column.

13. The phase shifter assembly according to claim 1, further comprising:
a drive mechanism, wherein the drive mechanism is connected to the second limiting structure and pushes the second circuit board to move relative to the first circuit board by means of the second limiting structure.

14. The phase shifter assembly according to claim 13, wherein the drive mechanism comprises a motor, a transmission piece and a connecting piece, the motor is connected to the transmission piece, and the transmission piece is connected to the connecting piece; and
the second limiting structure is provided with a connecting column connected to the connecting piece.

15. The phase shifter assembly according to claim 1, wherein the second circuit board is clamped between the first circuit board and the first limiting structure in a first direction, the second circuit board moves in a plane particular to the first direction.
